(19) United States
(12) Patent Application Publication
(10) Pub. No.: US 2015/0351231 A1
(43) Pub. Date: Dec. 3, 2015

(54) CIRCUIT BOARD AND METHOD OF MANUFACTURING CIRCUIT BOARD

(71) Applicant: SAMSUNG ELECTRO-MECHANICS CO., LTD., Suwon-Si (KR)

(72) Inventors: Young Kwan LEE, Changwon-si (KR); Myung Sam KANG, Hwaseong-si (KR); Seung Yeop KOOK, Busan (KR); Kwang Hee KWON, Busan (KR); Seung Eun LEE, Seongnam-si (KR); Ki Jung SUNG, Seoul (KR)

(21) Appl. No.: 14/722,066

(22) Filed: May 26, 2015

(30) Foreign Application Priority Data
May 28, 2014 (KR) 10-2014-0064494

(51) Int. Cl. H05K 1/02; H05K 3/30; H05K 3/00; H05K 3/40; H05K 1/11; H05K 1/09

(52) U.S. Cl. CPC H05K 1/0271; H05K 1/111; H05K 1/09; H05K 3/0014; H05K 3/4015; H05K 3/301; H05K 2201/10674; H05K 2201/068

(57) ABSTRACT

Disclosed herein is a circuit board in which a metal plate is provided on a surface coupled to a device, and a connection pad is exposed through an opening part of the metal plate to be electrically connected to the device. The circuit board may have the device mounted thereon and a connection terminal of the device and a connection pad of the circuit board may be connected to each other by a wire, or the like.

This application claims the benefit under 35 U.S.C. Section 119 of Korean Patent Application Serial No. 10-2014-0064494 entitled “Circuit Board and Method of Manufacturing Circuit Board” filed on May 28, 2014, which is hereby incorporated by reference in its entirety into this application.

### BACKGROUND OF THE INVENTION

1. Technical Field

An exemplary embodiment of the present invention relates to a circuit board.

2. Description of the Related Art

In accordance with a trend toward miniaturization, slimness, and high densification of a variety of electronic products such as a smartphone, and the like, efforts to increase a degree of integration of a main board, a package board, or the like mounted on the electronic product and decrease a thickness thereof have continued.

However, as a thickness of a circuit board such as the main board, or the like becomes thin, a problem caused by a warpage phenomenon, that is, a warpage problem has become serious.

Particularly, in case of an electronic component package manufactured by a method in which an electronic component such as an application processor, a memory element, or the like is mounted on the circuit board, which is then molded by a molding material such as an epoxy molding compound (EMC), or the like, a problem caused by the warpage phenomenon is serious due to relatively high coefficient of thermal expansion of the molding material such as the EMC, or the like and a problem caused by heat generated from the electronic component is also serious.

### RELATED ART DOCUMENT

### Patent Document

(Patent Document 1) US 2010-0288549 A1

### SUMMARY OF THE INVENTION

An object of the present invention is to provide a circuit board capable of implementing slimness and reducing warpage at the same time.

Another object of the present invention is to provide a circuit board capable of reducing warpage and improving heat radiation performance at the same time.

Another object of the present invention is to provide a method of manufacturing a circuit board capable of reducing warpage and improving manufacturing efficiency.

According to an exemplary embodiment of the present invention, there is provided a circuit board having a metal plate formed on one surface thereof, for example, a surface having a device coupled thereto.

A connection pad may be exposed through an opening part of the metal plate and the exposed connection pad and the device may be electrically connected to each other. At least one surface of the metal plate may be provided with an insulating material.

According to an exemplary embodiment of the present invention, there is provided a method of manufacturing a circuit board including forming a connection pad and an insulating layer on one surface of a metal plate, wherein an opening part exposing at least a part of the connection pad is formed in the metal plate.

The second connection pad may be formed on the other surface of the insulating layer and the second connection pad may be electrically connected to the first connection pad.

### BRIEF DESCRIPTION OF THE DRAWINGS

FIG. 1 is a cross-sectional view schematically showing a state in which a device is mounted on a circuit board according to an exemplary embodiment of the present invention;

FIG. 2 is an enlarged perspective view of part A of FIG. 1;

FIG. 3 is a cross-sectional view schematically showing a state in which a device is mounted on a circuit board according to another exemplary embodiment of the present invention;

FIG. 4 is an enlarged perspective view of part A of FIG. 3;

FIG. 5 is a cross-sectional view schematically showing a state in which a device is mounted on a circuit board according to another exemplary embodiment of the present invention;

FIGS. 6A to 6L are process cross-sectional views for describing a method of manufacturing a circuit board according to an exemplary embodiment of the present invention, wherein

FIG. 6A schematically illustrates a state in which a first insulating material is formed on a metal plate;

FIG. 6B schematically illustrates a state in which a seed layer is further formed on the first insulating material;

FIG. 6C schematically illustrates a state in which a resist pattern is further formed on the seed layer;

FIG. 6D schematically illustrates a state in which a first circuit pattern is further formed;

FIG. 6E schematically illustrates a state in which the resist pattern and the remaining seed layer are removed;

FIG. 6F schematically illustrates a state in which a first insulating layer is further formed;

FIG. 6G schematically illustrates a state in which a second circuit pattern is further formed;

FIG. 6H schematically illustrates a state in which a second insulating layer is further formed;

FIG. 6I schematically illustrates a state in which the resist pattern is further formed on a surface of the metal plate;

FIG. 6J schematically illustrates a state in which a first opening part is formed;

FIG. 6K schematically illustrates a state in which the resist pattern is removed; and

FIG. 6L schematically illustrates a state in which a pad plating part is further formed; and

FIG. 7 is a cross-sectional view for describing a method of manufacturing a circuit board according to another exemplary embodiment of the present invention.

### DESCRIPTION OF THE PREFERRED EMBODIMENTS

Various advantages and features of the present invention and methods accomplishing thereof will become apparent from the following description of exemplary embodiments with reference to the accompanying drawings. However, the present invention may be modified in many different forms and it should not be limited to exemplary embodiments set forth herein. These exemplary embodiments may be provided so that this disclosure will be thorough and complete, and will fully convey the scope of the invention to those skilled in the art. Like reference numerals throughout the description denote like elements.

Terms used in the present specification are for explaining exemplary embodiments rather than limiting the present invention. Unless explicitly described to the contrary, a singular form includes a plural form in the present specification. The word ‘comprise’ and/or ‘comprising’ used in the present specification will be understood to imply the inclusion of stated components, steps, operations and/or elements but not the exclusion of any other components, steps, operations and/or elements.

For simplification and clearness of illustration, a general configuration scheme will be shown in the accompanying drawings, and a detailed description of the feature and the technology well known in the art will be omitted in order to prevent a discussion of exemplary embodiments of the present invention from being unnecessarily obscure. Additionally, components shown in the accompanying drawings are not necessarily shown to scale. For example, sizes of some components shown in the accompanying drawings may be exaggerated as compared with other components in order to assist in understanding of exemplary embodiments of the present invention. Like reference numerals on different drawings will denote like components, and similar reference numerals on different drawings will denote similar components, but are not necessarily limited thereto.

In the specification and the claims, terms such as “first”, “second”, “third”, “fourth”, and the like, if any, will be used to distinguish similar components from each other and be used to describe a specific sequence or a generation sequence, but are not necessarily limited thereto. It may be understood that these terms are compatible with each other under an appropriate environment so that exemplary embodiments of the present invention to be described below may be operated in a sequence different from a sequence shown or described herein. Likewise, in the present specification, in the case in which it is described that a method includes a series of steps, a sequence of these steps suggested herein is not necessarily a sequence in which these steps may be executed. That is, any described step may be omitted and/or any other step that is not described herein may be added to the method.

In the specification and the claims, terms such as “left”, “right”, “front”, “rear”, “top, “bottom”, “over”, “under”, and the like, if any, do not necessarily indicate relative positions that are not changed, but are used for description. It may be understood that these terms are compatible with each other under an appropriate environment so that exemplary embodiments of the present invention to be described below may be operated in a direction different from a direction shown or described herein. A term “connected” used herein is defined as being directly or indirectly connected in an electrical or non-electrical scheme. Targets described as being “adjacent to” each other may physically contact each other, be close to each other, or be in the same general range or region, in the context in which the above phrase is used. Here, a phrase “in an exemplary embodiment” means the same exemplary embodiment, but is not necessarily limited thereto.

Hereinafter, a configuration and an acting effect of exemplary embodiments of the present invention will be described in more detail with reference to the accompanying drawings.

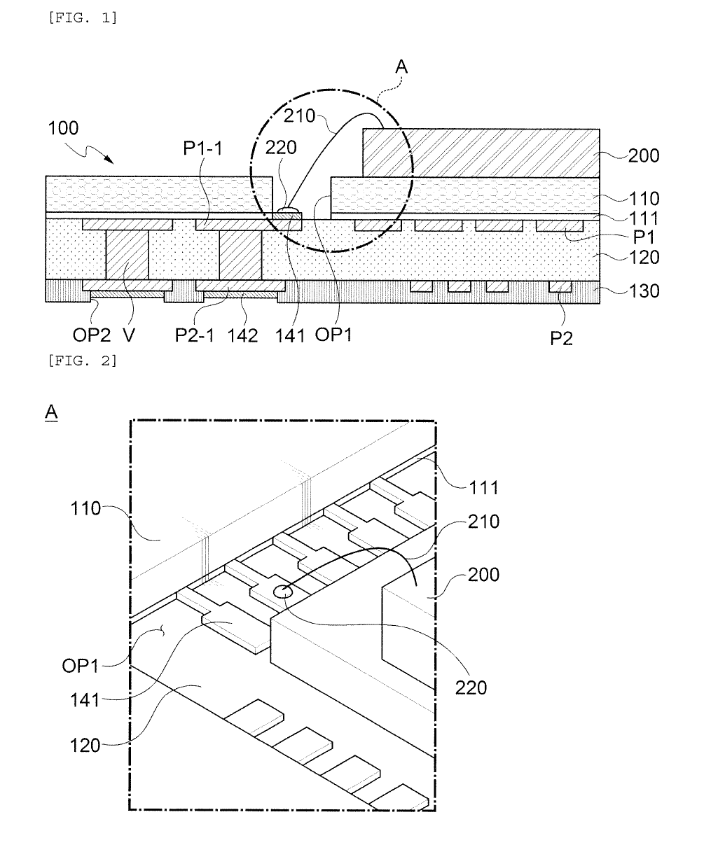

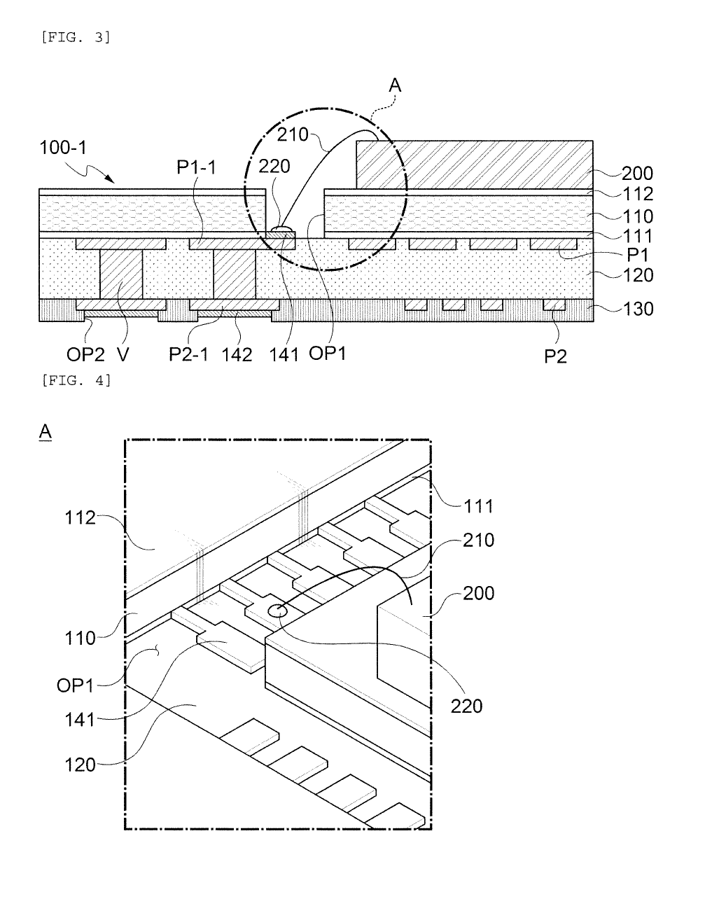

FIG. 1 is a cross-sectional view schematically showing a state in which a device 200 is mounted on a circuit board 100 according to an exemplary embodiment of the present invention and FIG. 2 is an enlarged perspective view of part A of FIG. 1.

Referring to FIGS. 1 and 2, the circuit board 100 according to the exemplary embodiment of the present invention includes a metal plate 100 having a first opening part OP1.

In the exemplary embodiment of the present invention, the metal plate 110 may be integrally made of a metal material.

In this case, a material having low coefficient of thermal expansion is used as the metal material implementing the metal plate 110, thereby making it possible to reduce a warpage phenomenon. By way of example, the metal plate 110 may be implemented by a material including invar or an invar alloy.

According to the exemplary embodiment of the present invention, one surface of the metal plate 110 has a circuit pattern, an insulating layer, or the like coupled thereto, and the other surface thereof has the device 200 such as an application processor, a memory element, or the like coupled thereto. In this case, a surface of the device 200 may be directly connected to the other surface of the metal plate 110.

Accordingly, warpage caused during a process of coupling the device 200 to the circuit board 100 may be further reduced and heat generated from the device 200 may be rapidly dissipated through the metal plate 110 at the same time.

Meanwhile, the first opening part OP1 provided in the metal plate 110 exposes a first connection pad P1-1 to the outside. Accordingly, the device 200 and the first connection pad P1-1 may be electrically connected to each other. According to the exemplary embodiment of the present invention, the device 200 and the first connection pad P1-1 may be electrically connected to each other by a wire 210. In this case, a solder 220 may be used so that the wire 210 may be stably fixed to the first connection pad P1-1. A connection scheme implemented by the wire 210 as described above may be referred to a wire bonding scheme.

In this case, a first pad plating part 141 may be formed on a surface of the first connection pad P1-1, particularly, a surface exposed through the first opening part OP1.

According to the exemplary embodiment of the present invention, the first connection pad P1-1 may be made of a conductive material such as copper, or the like. In addition, the first pad plating part 141 serves to prevent oxidation or pollution of the surface of the first connection pad P1-1, allow the wire 210, the solder 220, or the like to be closely coupled to the first connection pad P1-1, and so on. According to the exemplary embodiment of the present invention, the first pad plating part 141 may be implemented by a gold plating. If necessary, the first pad plating part 141 may be implemented by a nickel plating. Further, the first pad plating part 141 may be formed by sequentially forming a nickel plating layer and a gold plating layer on the surface of the first connection pad P1-1. In addition, the first pad plating part 141 may be implemented by an alloy containing at least one of nickel and gold.

Meanwhile, according to the exemplary embodiment of the present invention, a first circuit pattern P1, a first insulating layer 120, and the like may be further provided on a lower part of the metal plate 110. In this case, when the metal plate 110 and the first circuit pattern P1 are directly brought into contact with each other, it is apprehended that an unintended electrical connection is generated. Therefore, the circuit board 100 according to the exemplary embodiment of the present invention may further include a first insulating material 111 provided on one surface of the metal plate 110. Accordingly, a phenomenon in which the first circuit patterns P1 are unintendedly electrically connected to each other by the metal plate 110 may be prevented.

In addition, a plurality of first circuit patterns P1 may be formed, wherein a portion of the plurality of first circuit patterns P1 may serve as the first connection pad P1-1.

Meanwhile, according to the exemplary embodiment of the present invention, the first circuit pattern P1 or the first connection pad P1-1 may be electrically connected to the other surface of the first insulating layer 120 by a via V penetrating through the first insulating layer 120. In addition, a second connection pad P2-1 is directly or indirectly connected to the via V, such that an electrical connection structure having the order of the device 200, the first connection pad P1-1, and the second connection pad P2-1 may be implemented. Accordingly, efficiency of a process in which a kind of electronic component package having the device 200 mounted on one surface thereof is mounted on a main board, or the like may be improved.

Here, although FIG. 1, and the like illustrate a case in which the first connection pad P1-1 and the second connection pad P2-1 are each provided on both surface of the first insulating layer 120, an insulating layer and a circuit pattern may be further provided, if necessary.

According to the exemplary embodiment of the present invention, the other surface of the first insulating layer 120 is provided with a second insulating layer 130 covering the second circuit pattern P2, the second connection pad P2-1, and the first insulating layer 120. In this case, when the second insulating layer 130 is positioned at the outermost portion of the circuit board 100, the second insulating layer 130 may be made of solder resist.

In addition, the second insulating layer 130 may be provided with a second opening part OP2 exposing at least a part of the second connection pad P2-1.

In addition, the exposed surface of the second connection pad P2-1 may be provided with a second pad plating part 142 by a principal similar to the first pad plating part 141 as described above, and since a detailed description of the second pad plating part 142 is overlapped with that as described above, it will be omitted.

Accordingly, the second insulating layer 130 may serve to protect the second circuit pattern P2 and the first insulating layer 120. For example, the second insulating layer 130 may prevent a phenomenon in which the second circuit pattern P2 formed on the first insulating layer 120 is exposed to the outside and is polluted. In addition, even in the case in which the circuit board 100 is mounted on a main board (not shown), the second circuit pattern P2 on the first insulating layer 120 is not influenced by damage, or the like. In addition, in the case in which a solder (not shown), a solder ball (not shown), or the like is used to electrically connect the main board and the second connection pad P2-1 to each other, a phenomenon in which the second circuit pattern P2 is polluted by the solder, or the like or the second circuit patterns P2 adjacent to each other are unintendedly connected by the solder may be prevented.

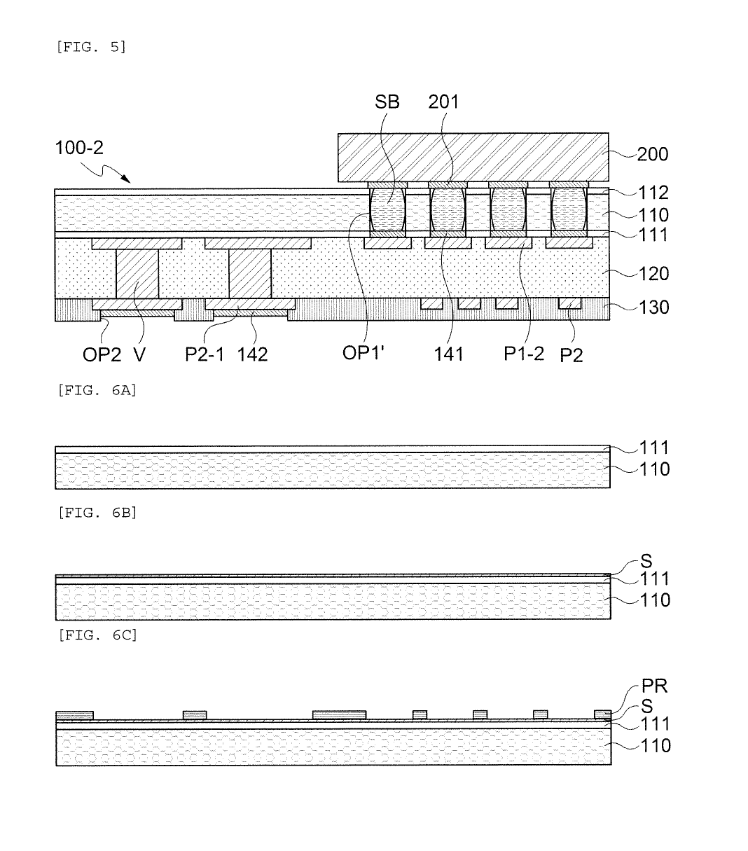

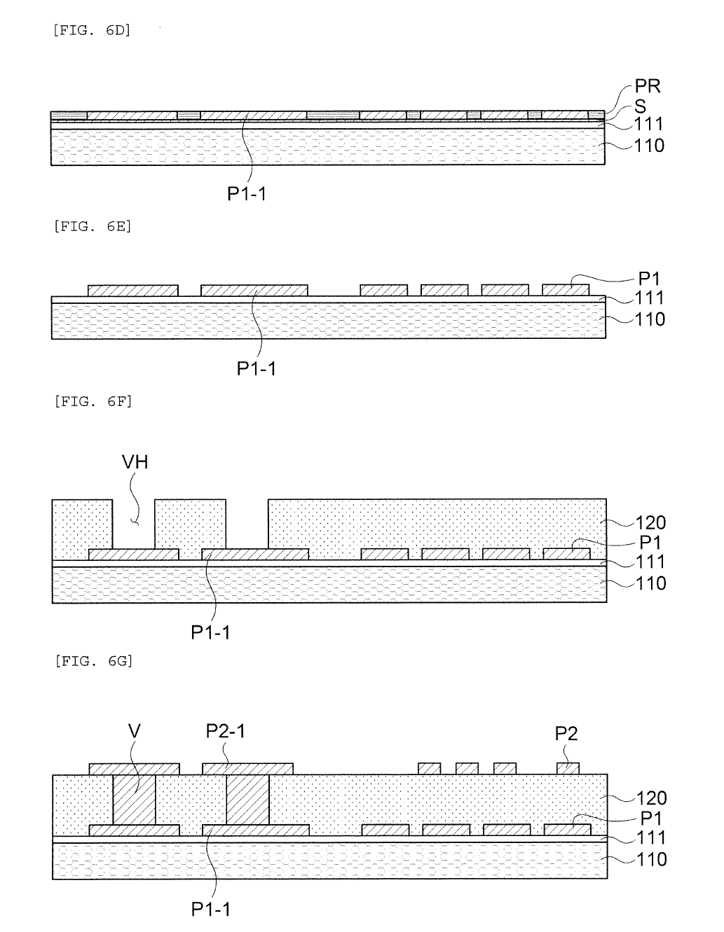

FIG. 3 is a cross-sectional view schematically showing a state in which a device 200 is mounted on a circuit board 100-1 according to another exemplary embodiment of the present invention and FIG. 4 is an enlarged perspective view of part A of FIG. 3.

Referring to FIGS. 3 and 4, the circuit board 100-1 according to another exemplary embodiment of the present invention is different from the exemplary embodiment described with reference to FIG. 1, or the like in that a second insulating material 112 is provided on the other surface of the metal plate 110.

The present exemplary embodiment may be used for a case in which insulation problem occurs as a surface of the device 200 and the other surface of the metal plate 110 are directly in contact with each other, or the like. For example, in the case in which wiring patterns (not shown), terminals (not shown), or the like is formed on the surface of the device 200, an unintended electrical connection may be implemented as the wiring patterns are in contact with the other surface of the metal plate 110. Therefore, in order to prevent the above-mentioned phenomenon, the second insulating material 112 may be provided on the other surface of the metal plate 110.

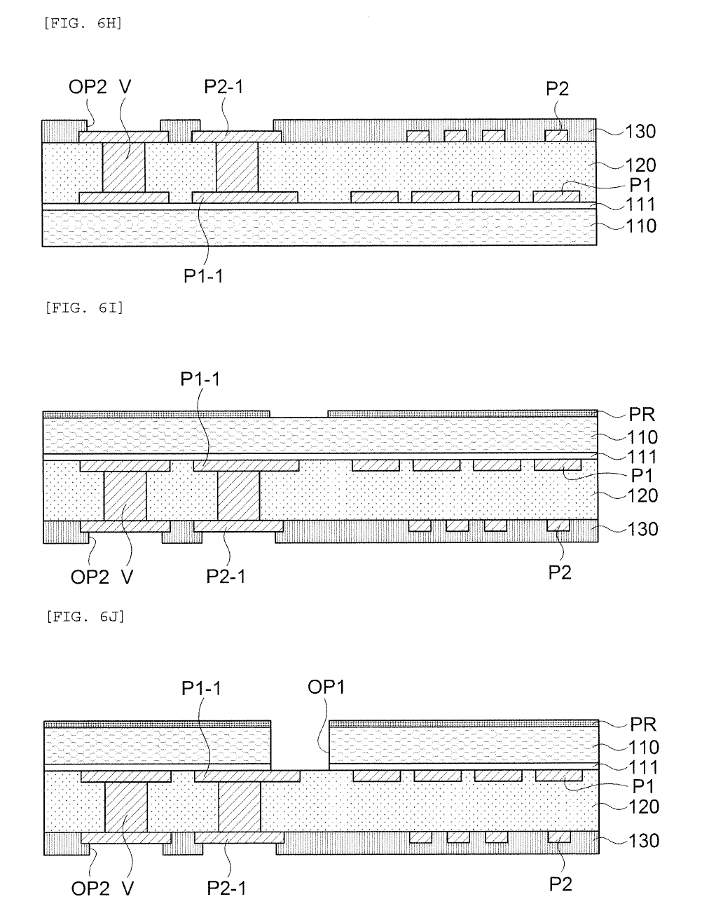

FIG. 5 is a cross-sectional view schematically showing a state in which a device 200 is mounted on a circuit board 100-2 according to another exemplary embodiment of the present invention.

Referring to FIG. 5, the circuit board 100-2 according to another exemplary embodiment of the present invention has the device 200 and a first connection pad P1-2 connected by solder balls SB. Here, a scheme of implementing a connection of the device 200 by providing a plurality of solder balls SB may be referred to as a flip chip bonding scheme. The device 200 mounted on the circuit board 100-2 by the above-mentioned flip chip bonding scheme may include an external terminal 201 exposed to an outer surface thereof.

In addition, since a short circuit may possibly occur in the case in which the external terminal 201 is directly in contact with the other surface of the metal plate 110, the second insulating material 112 may be provided on the other surface of the metal plate 110, as described with reference to FIG. 3, or the like.

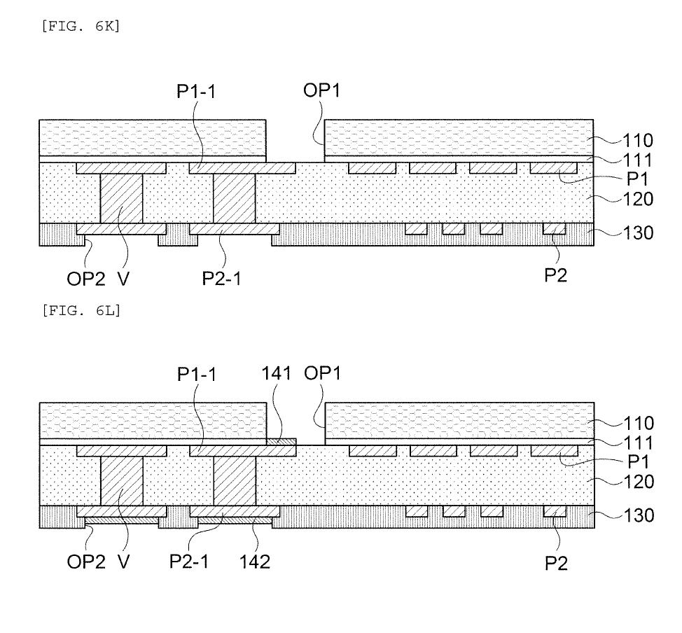

FIGS. 6A to 6L are process cross-sectional views for describing a method of manufacturing a circuit board according to an exemplary embodiment of the present invention.

Referring to FIGS. 6A to 6L, with the method of manufacturing the circuit board according to the exemplary embodiment of the present invention, the circuit board 100 including the metal plate 110 may be manufactured.

First, referring to FIG. 6A, the first insulating material 111 may be formed on the metal plate 110. Here, the first insulating material 111 or the second insulating material 112 of FIG. 3, or the like may be implemented by resin having insulating property. According to the exemplary embodiment of the present invention, the first insulating material 111 or the second insulating material 112 may be provided to a manufacturing process in a state in which the resin is applied onto one surface or both surfaces of the metal plate 110.

Next, referring to FIG. 6B, a seed layer S is formed on the first insulating material 111. In this case, the seed layer S may be made of a conductive material such as copper, or the like, and according to the exemplary embodiment of the present invention, the seed layer may be formed by a sputtering process.

Next, referring to FIG. 6C, after resist is applied onto the seed layer S, a resist pattern PR for forming a first circuit pattern P1 may be prepared. Here, as the resist, a dry film resist (DFR), or the like may be utilized, and the resist pattern PR may be formed by performing exposure and development processes.

Next, referring to FIG. 6D, the first circuit pattern P1 is formed by performing a plating process using the seed layer S and the resist pattern PR.

Next, referring to FIG. 6E, the first circuit pattern P1 may be completed by removing the resist pattern PR and the remaining seed layer S. Here, the first circuit pattern P1 may also include the first connection pad P1-1.

Next, referring to FIG. 6F, the first insulating layer 120 covering the first circuit pattern P1, the first connection pad P1-1, and the first insulating material 111 is formed. In addition, a via hole VH penetrating through the first insulating layer 120 and exposing at least a part of the first connection pad P1-1 may be formed. Although not shown, a via hole penetrating through the first insulating layer 120 and exposing the first circuit pattern P1 may also be formed, if necessary.

Next, referring to FIG. 6G, a via V being in contact with the first connection pad P1-1, a second connection pad P2-1 being in contact with the via V, a second circuit pattern P2, and the like may be formed on the first insulating layer 120.

Next, referring to FIG. 6H, a second insulating layer 130 covering the second circuit pattern P2, the second connection pad P2-1, and the first insulating layer 120 is formed. In this case, the second insulating layer 130 may be made of the solder resist as described above. In addition, the second insulating layer 130 may be provided with a second opening part OP2 exposing at least a part of the second connection pad P2-1.

Next, referring to FIG. 6I, a resist pattern PR is formed on the surface of the metal plate 110. The resist pattern PR is to form the first opening part OP1 described above in the metal plate 110.

Next, referring to FIG. 6J, the first opening part OP1 may be formed by removing a region of the metal plate 110 exposed from the resist pattern PR.

Next, referring to FIG. 6K, the resist pattern PR and the first insulating material 111 in a region exposed to the first opening part OP1 are removed.

Next, referring to FIG. 6L, a first pad plating part 141 may be formed on a surface of the first connection pad P1-1 exposed through the first opening part OP1. In this process, a second pad plating part 142 may also be formed on a surface of the second connection pad P2-1 exposed to the outside of the second insulating layer 130 through a second opening part OP2.

The device 200 may be mounted on the circuit board 100 manufactured as described above, and the warpage phenomenon which may be caused during a process of mounting the device 200 may be reduced. In addition, by appropriately adjusting a thickness of the metal plate 110, a thickness of the circuit board 100 may be reduced while the warpage is reduced.

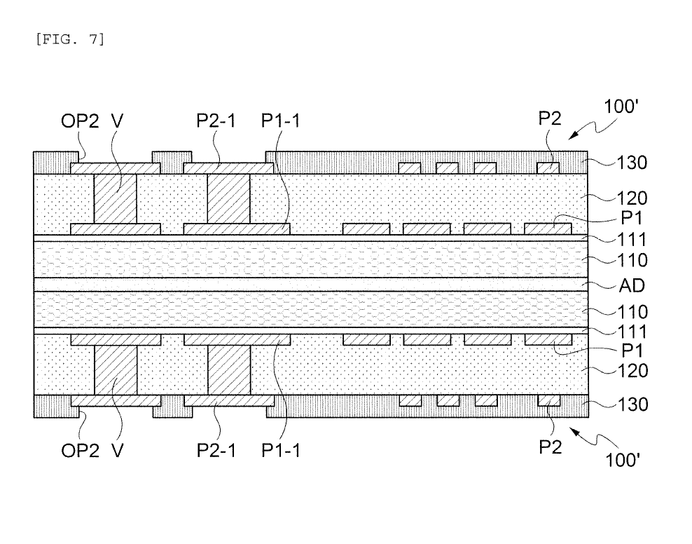

FIG. 7 is a cross-sectional view for describing a method of manufacturing a circuit board according to another exemplary embodiment of the present invention.

Referring to FIG. 7, by using the method described with reference to FIGS. 6A to 6L in a state in which two metal plates 110 are each fixed on both surfaces of an adhesive AD, circuit boards corresponding to a multiple of two may be manufactured even though the same process is performed. FIG. 7 shows an example in which intermediate products 100′ corresponding to FIG. 6H are coupled to both surfaces of the adhesive AD. The circuit board 100 may be manufactured by separating the metal plate 110 form the adhesive AD and then performing processes corresponding to FIGS. 6I to 6L, in a state shown in FIG. 7.

According to the exemplary embodiment of the present invention, the warpage of the circuit board may be reduced.

According to the exemplary embodiment of the present invention, the heat radiation performance of the circuit board may be improved.

According to the exemplary embodiment of the present invention, the manufacturing efficiency of the circuit board capable of reducing the warpage or improving the heat radiation performance may be improved.

What is claimed is:

1. A circuit board, wherein a first opening part penetrating through a metal plate is provided in the metal plate having a first insulating material provided on one surface thereof, and a first connection pad for external device connection is exposed to a direction of the other surface of the metal plate through the first opening part.

2. The circuit board according to claim 1, wherein the metal plate is integrally formed.

3. The circuit board according to claim 2, wherein the external device is coupled to the other surface of the metal plate.

4. The circuit board according to claim 3, wherein a second insulating material is provided between the other surface of the metal plate and the external device.

5. The circuit board according to claim 1, wherein a first circuit pattern including the first connection pad is provided on a lower part of the first insulating material.

6. The circuit board according to claim 5, further comprising:
a first insulating layer having one surface covering the first circuit pattern and the other surface having a second circuit pattern provided thereon; and
a second connection pad provided on a lower part of the first insulating layer and electrically connected to the first connection pad.

7. The circuit board according to claim 6, further comprising a second insulating layer exposing at least a part of the second connection pad.

8. The circuit board according to claim 1, wherein an upper surface of the first connection pad is provided with a pad plating part made of a conductive material different from a material forming the first connection pad.

9. The circuit board according to claim 8, wherein the pad plating part is made of at least one material selected from nickel and gold or made of an ally including at least one material selected from nickel and gold.

10. The circuit board according to claim 1, wherein the metal plate is made of a material including invar or an invar alloy.

11. A circuit board comprising:
a first insulating layer having a first connection pad provided on an upper part thereof and a second connection pad provided on a lower part thereof, the second connection pad being electrically connected to the first connection pad; and
a metal plate positioned on the upper part of the first insulating layer, having a first insulating material provided on one surface thereof, and formed integrally with a first opening part exposing at least a part of the first connection pad.

12. The circuit board according to claim 11, further comprising a second insulating layer positioned at the lower part of the first insulating layer and exposing at least a part of the second connection pad.

13. The circuit board according to claim 11, wherein the metal plate is made of a material including invar or an invar alloy.

14. The circuit board according to claim 11, wherein an upper surface of the first connection pad is provided with a pad plating part made of a conductive material different from a material forming the first connection pad, and
the pad plating part is made of at least one material selected from nickel and gold or made of an ally including at least one material selected from nickel and gold.

15. A method of manufacturing a circuit board, the method comprising:
forming a first circuit pattern including a first connection pad on a surface of a first insulating material provided on one surface of a metal plate;
forming a first insulating layer covering the first circuit pattern; and
forming a first opening part exposing at least a part of the first connection pad in the metal plate.

16. The method according to claim 15, further comprising:
forming a second connection pad electrically connected to the first connection pad on an upper part of the first insulating layer; and
forming a second insulating layer exposing at least a part of the second connection pad and covering the remaining portion of the second connection pad.

17. The method according to claim 15, further comprising coupling an external device onto the other surface of the metal plate, the external device being coupled onto the other surface of the metal plate so that the first connection pad and the external device are electrically connected to each other,
wherein the external device and the first connection pad are connected to each other by a wire or a solder ball.

18. The method according to claim 15, wherein the metal plate is integrally made of a material including invar or an invar alloy.

19. The method according to claim 16, further comprising, before the forming of the second connection pad electrically connected to the first connection pad on the upper part of the first insulating layer, forming a via hole penetrating through the first insulating layer and exposing at least a part of the first connection pad, and filling the via hole.

20. The method according to claim 16, further comprising forming a pad plating part on at least a part of exposed surfaces of the first connection pad and the second connection pad,
wherein the pad plating part is made of at least one material selected from nickel and gold or made of an ally including at least one material selected from nickel and gold.
